(19) United States
(12) Patent Application Publication
(10) Pub. No.: US 2011/0019342 A1
(43) Pub. Date: Jan. 27, 2011

(54) REMOTE CONTROL

(76) Inventor: Justin Moore, Kuna, ID (US)

Correspondence Address: HOLLAND LAW OFFICE P.L.L.C., P.O. BOX 1840, BOISE, ID, 83701-1840, US

(21) Appl. No.: 12/509,851

(22) Filed: Jul. 27, 2009

(51) Int. Cl. H05K 5/00

(52) U.S. Cl. 361/679.01

(57) ABSTRACT

A remote control barrier operating device that is attachable to a handlebar steered vehicle, such as a motorcycle, bicycle or all terrain vehicle, is described and claimed. The remote control device includes a power source and a remote control barrier operating circuit for transmitting a radio frequency enclosed within a device housing. At least one attachment ear extends from the device housing, for attachment of the device housing to the vehicle. In one embodiment the remote control device is attachable as an accessory to the bar clamp for a handlebar of the vehicle. The remote control device is configured having a pair of attachment ears extending from the device housing, the attachment ears configured for alignment with and attachment to the bar clamp by a pair of screws that pass through the attachment ear apertures to engage one of a pair of threaded apertures of the bar clamp.

### BACKGROUND

Remote control barrier operating devices, including remote control garage door operating devices, are a common convenience. Remote control devices typically include a battery powered high frequency transmitter which operates on one or more frequencies. Commonly these devices include a housing adapted to contain a power supply and the circuitry necessary to provide the desired operability including signal transmission on a desired, preset or selectable frequency. Oftentimes the housing of the device is configured having a clip or other attachment means to permit mounting of the remote control device at a convenient location within the vehicle, for instance to the sun visor.

While automobile and other four wheeled vehicle operators enjoy the convenience of using any of a variety of remote control barrier operating device, a need remains to provide the same utility and convenience to operators of two wheeled vehicles including motorcycles. Other two wheeled vehicles that may benefit from a device adapted for use on handlebar steered vehicles include for instance bicycles, the operators of which may find convenience in operating any of a variety of remotely controlled motor operated barriers, including garage doors without having to free a hand to fumble through pockets or other storage or in the alternative dismount in order to locate a remote control device.

To the extent that one may attempt to attach a remote control device to a handlebar or other structure related to the steering head structure and function, a challenge has been to do it is such a manner that the remote control is securely attached in such a manner as not to interfere with the steering function or operation. Preferably the remote would be attached at or near an axis of rotation of the steering head so that the control is well within the line of sight and easy reach of the rider.

Thus, there is a need for a remote control barrier operating device for use with handlebar steered vehicles, such as motorcycles, bicycles and all terrain vehicles that may require access across or through a remote controlled barrier or access to a garage having a remote controlled door. Therefore one object of the present invention is to provide a remote control barrier operating device for attachment to a handlebar steered vehicle. Another object of the present invention is to provide a remote control barrier operating device that mounts to a steering head of a handlebar steered vehicle in such a manner as not to interfere with the steering function or operation. Another object of the present invention is to provide a housing that encloses an original equipment manufactured remote control barrier operating device or a universal remote control barrier operating device, the housing attachable to a handlebar steered vehicle.

### SUMMARY OF THE INVENTION

The present invention is directed to a remote control barrier operating device that is attachable to a handlebar steered vehicle. The remote control barrier operating device of the present invention includes a power source and a remote control barrier operating circuit enclosed within the device housing. The remote control barrier operating circuit is connected to the power source. A push button switch accessible and operable through a sidewall of the device housing actuates the remote control barrier operating circuit to transmit a radio frequency (RF). At least one attachment ear extends from the device housing, the attachment ear adapted to permit attachment of the device housing to the handlebar steered vehicle.

In a preferred embodiment of the invention a remote control barrier operating device is provided which is adapted to be attached as an accessory to the bar clamp for a handlebar of a handlebar steered vehicle such as a motorcycle, bicycle or all terrain vehicle. The remote control barrier operating device is preferably configured having a pair of attachment ears, each attachment ear connected to and extending from the device housing, each ear including an aperture, the distance between apertures being substantially equal to a distance between a pair of threaded apertures of the bar clamp, each attachment ear aperture adapted to permit insertion of a screw through the attachment ear aperture to engage one of a pair of threaded apertures of the bar clamp.

In accordance with another aspect of the present invention a remote control barrier operating device is provided which includes a removable panel that allows access to the power source and a remote control barrier operating circuit without complete removal of the remote control barrier operating device from the handlebar steered vehicle. An alternate embodiment of the invention relies on providing the requisite connectivity to draw power for operation of the remote control barrier operating circuit, rather that enclosing a separate power source in the device housing with the circuit.

Upon reading the detailed description which follows in conjunction with the drawings, t hose skilled in the art will further appreciate the above-noted features and advantages of the invention together with other important aspects thereof.

### BRIEF DESCRIPTION OF THE DRAWINGS

FIG. 1 is a representative perspective view of the remote control of the present invention;

FIG. 2 is a representative perspective view showing a portion of a motorcycle showing the remote control of the present invention mounted thereon;

FIG. 3 is a representative cross section of bar clamp handlebar assembly to which the remote control of the present invention has been attached;

FIG. 4 is a representative exploded cross section bar clamp handlebar assembly to which the remote control of the present invention is being attached;

FIG. 5 is an exploded view of the remote control showing certain details of the components of the unit; and

FIG. 6 is an exploded view of the remote control showing certain details of the components of the unit.

### DETAILED DESCRIPTION OF THE PREFERRED EMBODIMENT

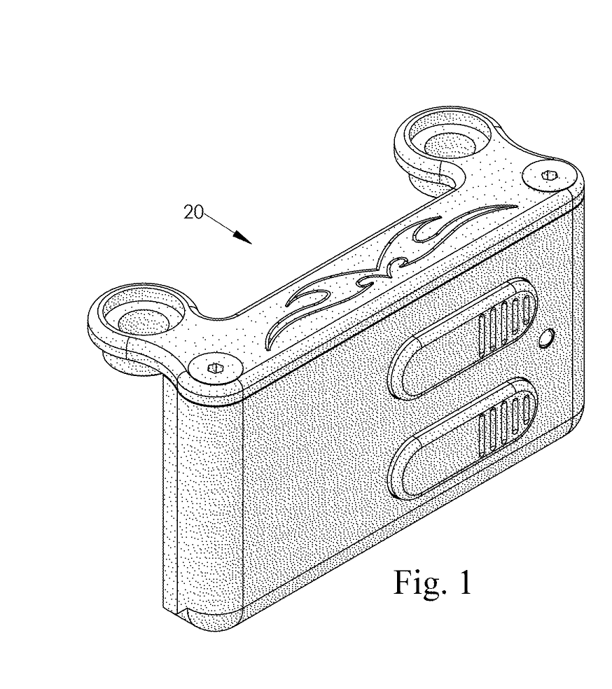

Referring to FIG. 1, remote control barrier operating device 20 is shown including of device housing 21 having a pair of attachment ears 22 attached to and extending there from. Each attachment ear 22 is configured having aperture 26 that projects through the ear 22. Aperture 26 includes counterbore 27. Remote control barrier operating device 20 also includes one or more switches 35 that operate the various functions of remote control barrier operating device 20. An optical indicator, for instance LED 36 provides visual output of circuit function and power status.

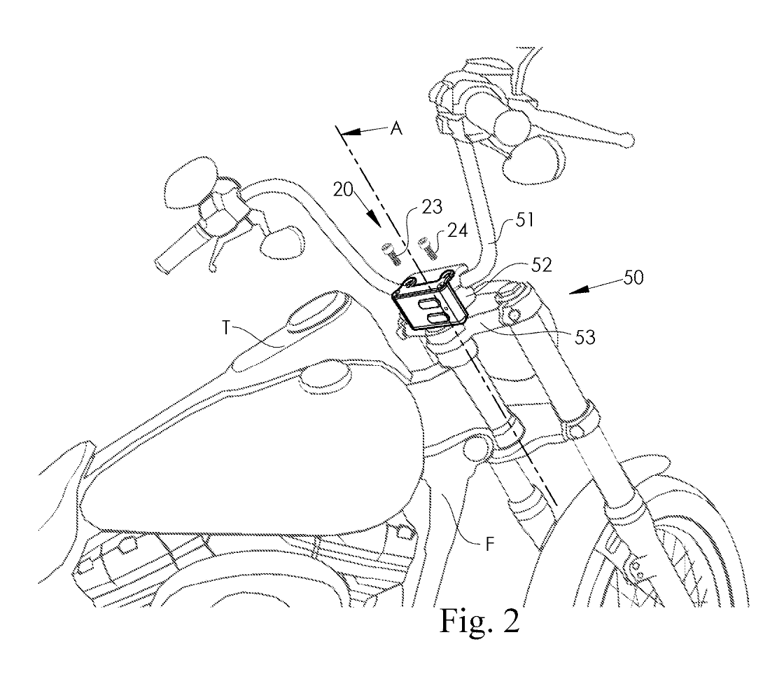

FIG. 2 depicts remote control barrier operating device 20 positioned for installation on motorcycle 50. Motorcycle 50 includes frame F, fuel tank T and steering head 53 which rotates with respect to frame about an axis A. Motorcycle 50 also includes bar clamp 52 that holds handlebar 51 in a compressive grip relative to steering head 53 of motorcycle 50. This compressive grip is developed by bar clamp 52 against the tubular cross-section of handlebar 51 when a tightening force is applied to screws 23 and 24.

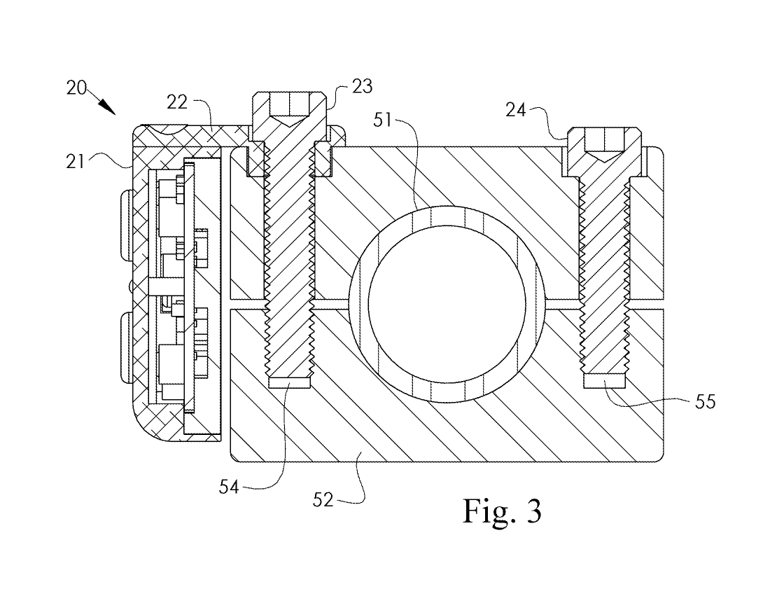

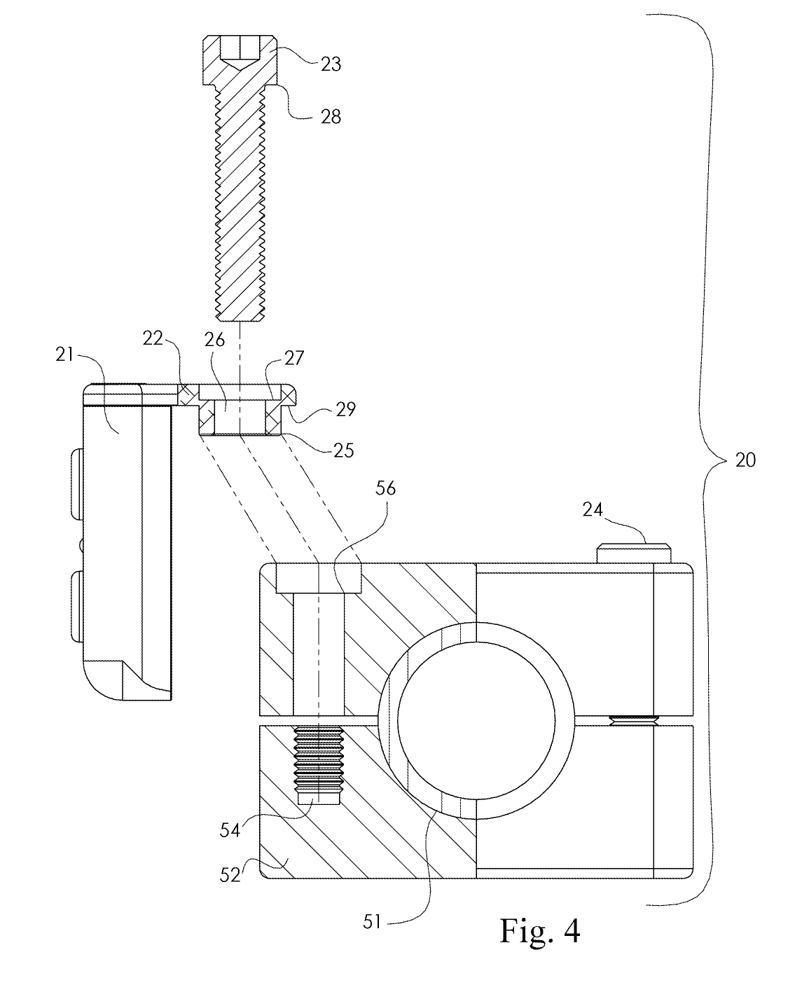

Referring to FIGS. 3 and 4, bar clamp 52, handlebar 51 and remote control barrier operating device 20 are shown. A gripping force is developed against handlebar 51 by bar clamp 52 when a tightening force is applied to screws 23 and 24 which engage bar clamp threaded apertures 54 and 55 respectively. Remote control barrier operating device 20 is shown including device housing 21 having attachment ear 22 extending there from. Attachment ear 22 includes aperture 26 formed therein In FIG. 3, remote control barrier operating device 20 is shown installed on bar clamp 52.

Referring to FIG. 4, attachment ear 22 is configured having shoulder 25 formed on mounting surface 29 at a site where aperture 26 projects through ear 22. Aperture 26 includes counterbore 27. Shoulder 25 included a generally circular cross-sectional configuration, adapted to fit in a counterbore of a threaded aperture. To install remote control barrier operating device 20, shoulder 25 of attachment ear 22 is fitted into bar clamp counterbore 56 of bar clamp threaded aperture 55. Screw 23 is inserted into and threadedly engages bar clamp threaded aperture 54. Head 28 of screw 23 tightens against counterbore 27 of aperture 26 and shoulder 25 tightens against bar clamp counterbore 56 as a gripping force is developed against handlebar 51 by bar clamp 52. The nested configuration of head 28, counterbore 27, shoulder 25 and bar clamp counterbore 56 provides a means for attaching remote control barrier operating device 20 to a bar clamp 52 that assures that the gripping force developed against handlebar 51 by bar clamp 52 is not diminished or jeopardized and the alignment of device housing 21 of remote control barrier operating device 20 with respect to bar clamp 52 and, referring to FIG. 2, the articulating structure of steering head 53 and the relatively stationary structure including the frame F and tank T of motorcycle 50.

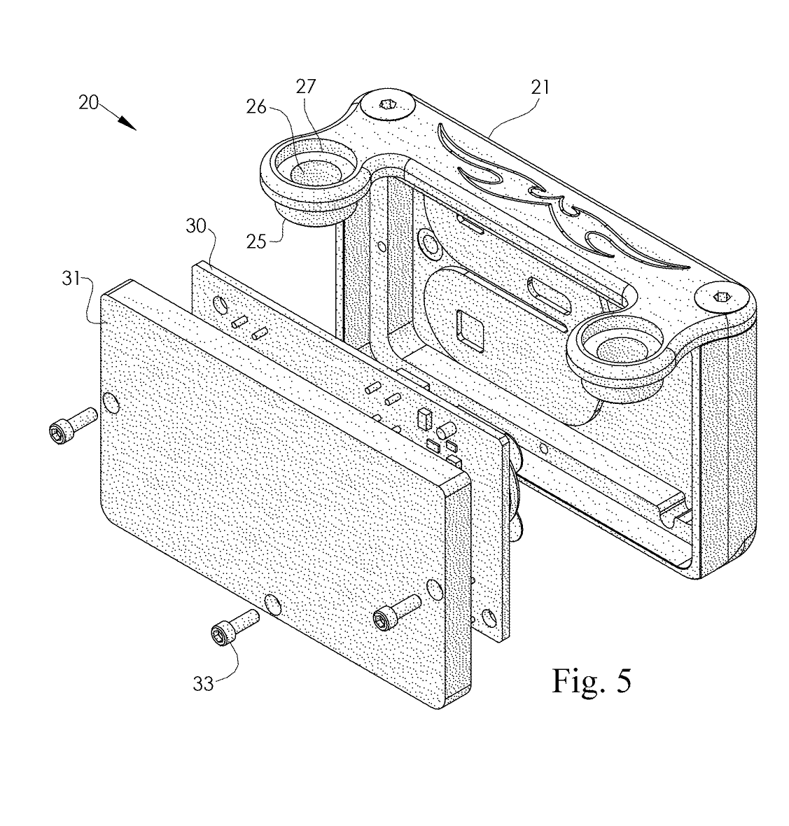

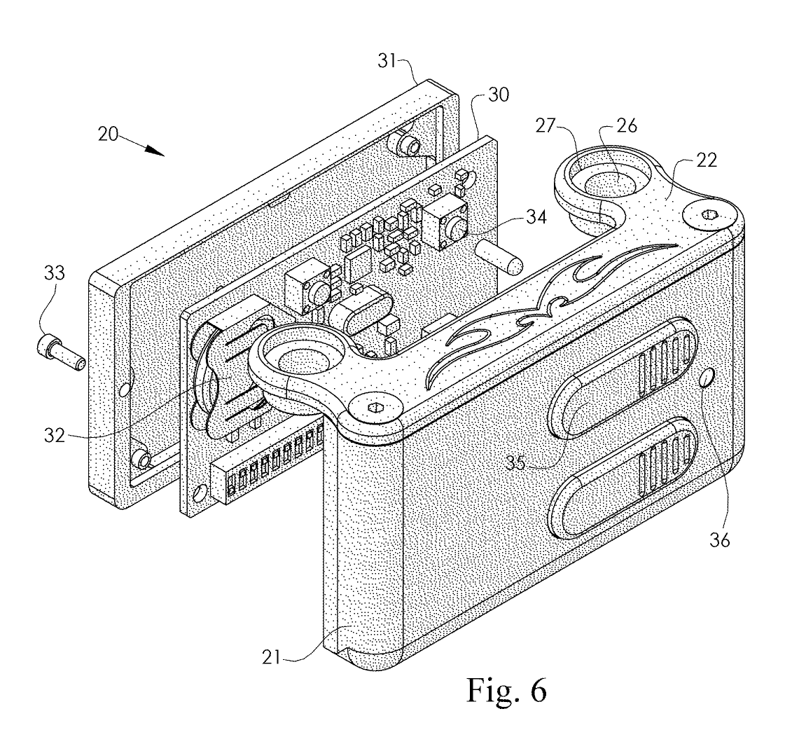

Referring to FIGS. 5 and 6, remote control barrier operating device 20 is shown including of device housing 21 having a pair of attachment ears 22 attached to and extending there from. Each attachment ear 22 is configured having shoulder 25 where aperture 26 projects through ear 22. Aperture 26 includes counterbore 27. Device housing 21 also includes removable rear panel 31 that is attachable by screws 33. Remote control barrier operating circuit 30 and power source 32, shown in FIG. 6, are shown enclosable within device housing 21. Remote control barrier operating circuit 30 includes a radio frequency transmitter circuit, any number of which, are well known in the art that is operable to transmit a signal to remotely control a barrier. With continued reference to FIG. 6, remote control barrier operating circuit 30 includes one or more switches 35 that operatively cooperate with one or more pressure pads 34 to operate the various functions of remote control barrier operating device 20. An optical indicator, for instance LED 36 provides visual output of circuit function and power status.

Remote control barrier operating device 20 provides a compact device which may be easily mounted on bar clamp 52 of a steering head 53 by an owner, operator or mechanic. Remote control barrier operating device 20 includes structure that permits safe attachment of the device to the bar clamp 52 in a manner that assures that the gripping force developed against handlebar 51 by bar clamp 52 is not diminished or jeopardized. Remote control barrier operating device 20 also provides a compact device that permits mounting of a remote control device near the axis or rotation of the articulating structure of steering head 53 well within the line of sight and easy reach of a rider while maintaining a safe and non-interfering distance from the relatively stationary structure including the frame F and tank T of motorcycle 50 so as not to impede the steering function.

Those skilled in the art will recognize that other modifications and substitutions may be provided with respect to the invention disclosed herein without departing from the scope and spirit of the appended claims.

What is claimed is:

1 A remote control barrier operating device attachable to a handlebar steered vehicle, the remote control barrier operating device comprising:
a device housing;
a power source enclosed in the device housing;
a remote control barrier operating circuit connected to the power source, the remote control barrier operating circuit enclosed in the device housing; and
an attachment ear attached to and extending from the device housing, the attachment ear adapted to permit attachment of the device housing to the handlebar steered vehicle.

2. The remote control of claim 1 wherein the attachment ear further comprises a shoulder formed on a mounting surface of the attachment ear, an aperture formed through the attachment ear extending through the shoulder, the shoulder including a generally circular cross-sectional configuration, adapted to fit in a counterbore of a threaded aperture located on the handlebar steered vehicle.

3. The remote control of claim 1 wherein the device housing further comprises:
a pair of attachment ears attached to and extending from the device housing;
each of the pair of attachment ears including a shoulder formed on a mounting surface of each of the pair of attachment ears, each shoulder including a generally circular cross-sectional configuration;
each of the pair of attachment ears including an aperture formed through each of the pair of attachment ears, the aperture extending through the shoulder, the pair of attachment ears having a distance between the attachment ears equal to a distance between a pair of threaded apertures formed on the handlebar steered vehicle, each of the pair of attachment ears adapted to permit insertion of an attachment screw for threaded engagement with one of the pair of threaded apertures on the motorcycle, each shoulder formed on one of the pair of attachment ears adapted to fit in a counterbore of one of the pair of threaded apertures on the motorcycle.

4. The remote control of claim 1 wherein the device housing further comprises:
a plurality of attachment ears attached to and extending from the device housing;
each of the plurality of attachment ears including a shoulder formed on a mounting surface of plurality of attachment ears, each shoulder including a generally circular cross-sectional configuration;
each of the plurality of attachment ears including an aperture formed through each of the plurality of attachment ears, the aperture extending through the shoulder, the plurality of attachment ears having a distance between each of the plurality of attachment ears equal to a distance between a plurality of threaded apertures formed on a handlebar steered vehicle, each of the plurality of attachment ears adapted to permit insertion of an attachment screw for threaded engagement with one of the plurality of threaded apertures on the motorcycle, each shoulder formed on each of the plurality of attachment ears adapted to fit in a counterbore of one of the plurality of threaded apertures on the motorcycle.

5. The remote control of claim 1 wherein the power source is replaceable.

6. The remote control of claim 1 wherein the wherein the remote control barrier operating circuit and the power source are removable from the device housing.

7. The remote control of claim 1 wherein the device housing includes an openable panel adapted to permit insertion of the remote control barrier operating circuit and the power source from the device housing.

8. A remote control barrier operating device attachable to a handlebar clamp of a handlebar steered vehicle, the remote control barrier operating device comprising:
a device housing;
a power source enclosed in the device housing;
a remote control barrier operating circuit connected to the power source, the remote control barrier operating circuit enclosed in the device housing; and
an attachment ear attached to and extending from the device housing, the attachment ear adapted to permit attachment of the device housing to the handlebar clamp of the handlebar steered vehicle.

9. The remote control of claim 8 wherein the attachment ear further comprises a shoulder formed on a mounting surface of the attachment ear, an aperture formed through the attachment ear extending through the shoulder, the shoulder including a generally circular cross-sectional configuration, adapted to fit in a counterbore of a threaded aperture located on the handlebar clamp of the handlebar steered vehicle.

10. The remote control of claim 8 wherein the device housing further comprises:
a pair of attachment ears attached to and extending from the device housing;
each of the pair of attachment ears including a shoulder formed on a mounting surface of each of the pair of attachment ears, each shoulder including a generally circular cross-sectional configuration;
each of the pair of attachment ears including an aperture formed through each of the pair of attachment ears, the aperture extending through the shoulder, each of the pair of attachment ears having a distance between each of the pair of attachment ears equal to a distance between a pair of threaded apertures formed on the handlebar clamp of the handlebar steered vehicle, each of the pair of attachment ears adapted to permit insertion of an attachment screw for threaded engagement with one of the pair of threaded apertures on the handlebar clamp of the handlebar steered vehicle, each shoulder formed on one of the pair of attachment ears adapted to fit in a counterbore of one of the pair of threaded apertures on the handlebar clamp of the handlebar steered vehicle.

11. The remote control of claim 8 wherein the device housing further comprises:
a plurality of attachment ears attached to and extending from the device housing;
each of the plurality of attachment ears including a shoulder formed on a mounting surface of each of the plurality of attachment ears, each shoulder including a generally circular cross-sectional configuration;
each of the plurality of attachment ears including an aperture formed through each of the plurality of attachment ears, the aperture extending through the shoulder, each of the plurality of attachment ears having a distance between each of the remaining plurality of attachment ears equal to a distance between a plurality of threaded apertures formed on the handlebar clamp of the handlebar steered vehicle, each of the plurality of attachment ears adapted to permit insertion of an attachment screw for threaded engagement with one of the plurality of threaded apertures on the handlebar clamp of the handlebar steered vehicle, each shoulder formed on each of the plurality of attachment ears adapted to fit in a counterbore of one of the plurality of threaded apertures on the handlebar clamp of the handlebar steered vehicle.

12. The remote control of claim 8 wherein the power source is replaceable.

13. The remote control of claim 8 wherein the wherein the remote control barrier operating circuit and the power source are removable from the device housing.

14. The remote control of claim 8 wherein the device housing includes an openable panel adapted to permit insertion of the remote control barrier operating circuit and the power source from the device housing.

15. A remote control barrier operating device attachable to a handlebar clamp of a handlebar steered vehicle, the remote control barrier operating device comprising:
a device housing;
a power source removably enclosed in the device housing;
a remote control barrier operating circuit connected to the power source, the remote control barrier operating circuit enclosed in the device housing;
a pair of attachment ears attached to and extending from the device housing;
each of the pair of attachment ears including a shoulder formed on a mounting surface of each of the pair of attachment ears, each shoulder including a generally circular cross-sectional configuration;
each of the pair of attachment ears including an aperture formed through each of the pair of attachment ears, the aperture extending through the shoulder, each of the pair of attachment ears having a distance between each of the pair of attachment ears equal to a distance between a pair of threaded apertures formed on the handlebar clamp of the handlebar steered vehicle, each of the pair of attachment ears adapted to permit insertion of an attachment screw for threaded engagement with one of the pair of threaded apertures of the handlebar clamp of the handlebar steered vehicle, each shoulder formed on one of the pair of attachment ears adapted to fit in a counterbore of one of the pair of threaded apertures on the handlebar clamp of the handlebar steered vehicle.

16. The remote control of claim 15 further comprising:
a primary circuit housing, the remote control barrier operating circuit and the power source enclosed in the primary circuit housing; and
the device housing including an openable panel adapted to permit removal of the primary circuit housing from the device housing.
